(19) United States
(12) Patent Application Publication
(10) Pub. No.: US 2020/0059110 A1
(43) Pub. Date: Feb. 20, 2020

(54) MULTIFUNCTION WIRELESS CHARGING PAD

(71) Applicant: CHANNEL WELL TECHNOLOGY CO., LTD., Taoyuan City (TW)

(72) Inventor: YI-AN PAN, Taoyuan City (TW)

(21) Appl. No.: 16/103,929

(22) Filed: Aug. 15, 2018

(51) Int. Cl. H02J 7/02; H02J 50/80; H05B 33/08; G01R 19/165; H04B 5/00; G08C 17/02

(52) U.S. Cl. CPC H02J 7/025; H02J 7/027; H02J 50/80; H05B 33/0896; H04R 1/028; G01R 19/16571; H04B 5/0037; H04B 5/0081; G08C 17/02; H05B 33/0842

(57) ABSTRACT

Disclosures of the present invention describe a multifunction wireless charging pad, which not only have functions of mouse pad and wireless charging, but also can transmit data to any kinds of wireless chargeable electronic devices by Bluetooth communication or near field communication. The multifunction wireless charging pad mainly consists of a body, a circuit module, and at least one lighting unit. During the using of this multifunction wireless charging pad, when one wireless chargeable electronic device such as a mouse or a smart phone is positioned on the multifunction wireless charging pad for electricity charging, a main controlling unit in the circuit module controls the lighting unit to emit a corresponding situation light, such that the charging state and/or the operation state of the wireless chargeable electronic device is able to be found out by reading the variation of the situation light.

### BACKGROUND OF THE INVENTION

### 1. Field of the Invention

The present invention relates to technology field of wireless chargers, and more particularly to a multifunction wireless charging pad integrated with lighting units.

### 2. Description of the Prior Art

With advancement of science and technology, personal desk computer, laptop computer, tablet PC and even portable mobile devices with various volume sizes have become necessary objects used in daily life and work of people. Mouse is one kind of input device for allowing users input a cursor controlling signal into the aforesaid electronic devices. In order to facilitate the operation of the mouse, a wide variety of wireless mice are developed and provided by manufacturers for replacing the traditional wired mice. However, with demands on function of mouse made by game players are getting more, for example, high sensitivity, multi auxiliary buttons and high performance, it is presumed that such multifunction mouse certainly have considerable power consumption during the operation thereof. Therefore, in the case of the fact that the power of the multifunction mouse is supplied by a disposable battery unit, it needs to replace the disposable battery unit by a new one as the electricity stored in the disposable battery has been run down. As a result, not only do used batteries must be recycled and then properly treated, but also users need to spend considerable cost for purchasing new disposable batteries. On the other hand, user always operates his mouse on a mouse pad for increased the accuracy and sensitivity of the cursor controlling.

Briefly speaking, although conventional wireless mouse has brought convenience of cursor controlling to user, battery capacity still limits the use time of the wireless mouse. Therefore, even though various exclusive chargers have been developed and provided for corresponding wireless mice, user still cannot use his wireless mouse during the fact that the wireless mice is putting on the charger for electricity charging, and that is very inconvenient for users.

Through above descriptions, it is known that wireless mouse still shows drawbacks and shortcomings in practical use. In view of that, inventors of the present application have made great efforts to make inventive research thereon and eventually provided a multifunction wireless charging pad.

### SUMMARY OF THE INVENTION

The primary objective of the present invention is to provide a multifunction wireless charging pad, not only having functions of mouse pad and wireless charging, but also capable of transmitting data to any kinds of wireless chargeable electronic devices by Bluetooth communication or near field communication. It is worth explaining that, the multifunction wireless charging pad mainly comprises a body, a circuit module and at least one lighting unit. During the using of this multifunction wireless charging pad, when one wireless chargeable electronic device such as a mouse or a smart phone is positioned on the multifunction wireless charging pad for electricity charging, a main controlling unit in the circuit module controls the lighting unit to emit a corresponding situation light, such that the charging state and/or the operation state of the wireless chargeable electronic device is able to be found out by reading the variation of the situation light. Furthermore, the multifunction wireless charging pad further provided a fast charging mode.

For achieving the primary objective of the present invention, the inventor of the present invention provides an embodiment for the multifunction wireless charging pad, comprising:
a body, being provided with a pad area and a wireless charging area thereon;
a circuit module, being accommodated in the body and coupled to a power source or a computer through an electrical connector; wherein the circuit module comprises a main controlling unit, a power supply unit, a current monitoring unit, and a first coil unit; and
at least one lighting unit, being connected to the body and coupled to a lighting driver unit;
wherein when a wireless chargeable electronic device having a battery charging unit and a battery is positioned in the wireless charging area, the main controlling unit enables the power supply unit to convert the power source to an electricity having a specific power;
wherein the electricity is further transmitted to a coil element of the wireless chargeable electronic device through the first coil unit, the battery charging unit is enabled to charge the battery by using the electricity.

### BRIEF DESCRIPTION OF THE DRAWINGS

The invention as well as a preferred mode of use and advantages thereof will be best understood by referring to the following detailed description of an illustrative embodiment in conjunction with the accompanying drawings, wherein:

FIG. 1 shows a stereo partially-exploded diagram of a first embodiment of a multifunction wireless charging pad according to the present invention;

FIG. 2 shows a first circuit block diagram of the first embodiment of the multifunction wireless charging pad;

FIG. 3 shows a diagram for describing the practical application of the first embodiment of the multifunction wireless charging pad;

FIG. 4 shows a second circuit block diagram of the first embodiment of the multifunction wireless charging pad;

FIG. 5 shows a top view of the first embodiment of the multifunction wireless charging pad;

FIG. 6 shows a stereo diagram of a second embodiment of the multifunction wireless charging pad;

FIG. 7 shows a circuit block diagram of the second embodiment of the multifunction wireless charging pad; and

FIG. 8 shows a circuit block diagram of a third embodiment of the multifunction wireless charging pad.

### DETAILED DESCRIPTION OF THE PREFERRED EMBODIMENTS

To more clearly describe a multifunction wireless charging pad, embodiments of the present invention will be described in detail with reference to the attached drawings hereinafter.

### First Embodiment

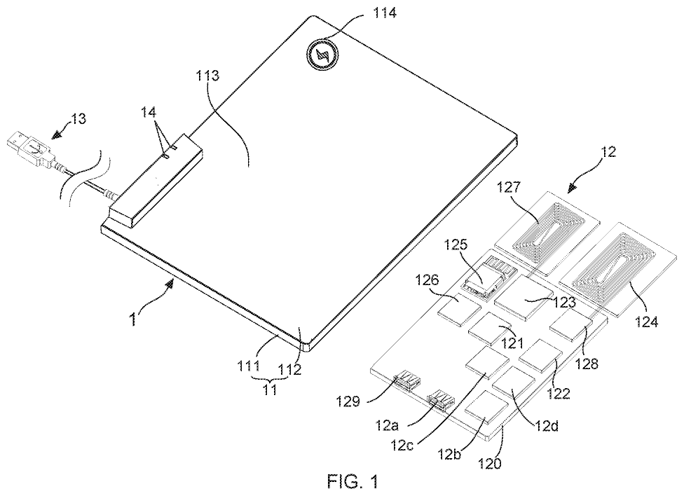

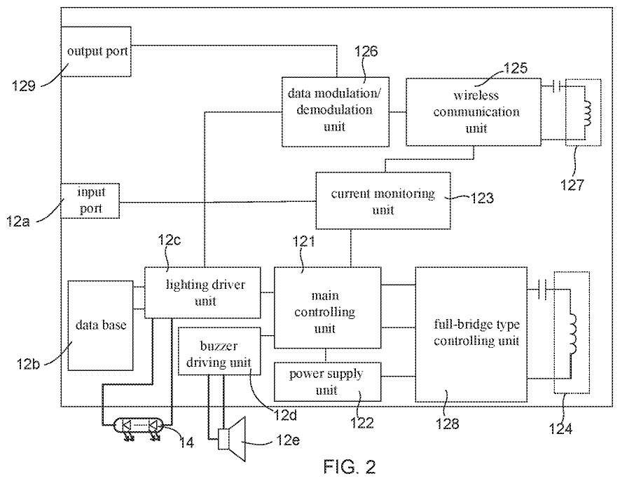

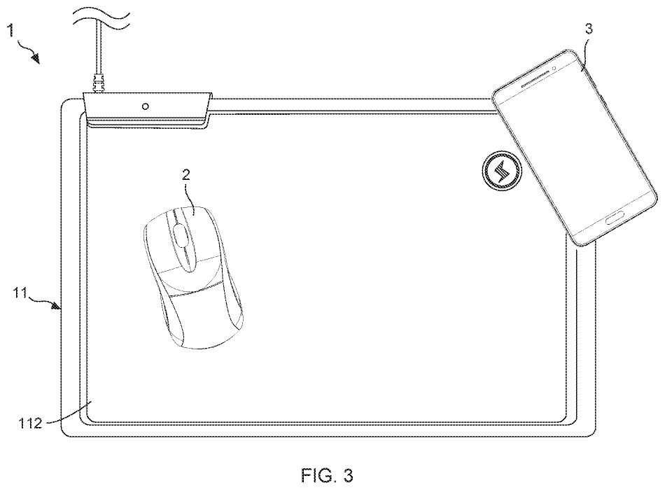

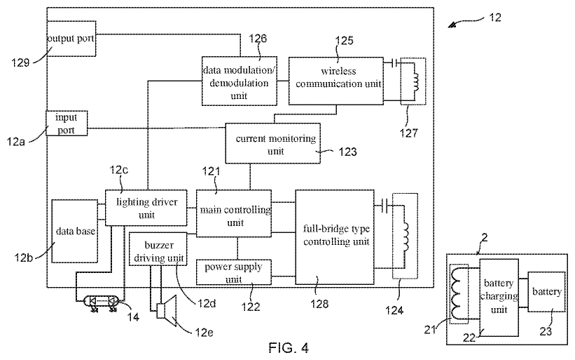

With reference to FIG. 1, there is provided a partially-exploded stereo diagram of a first embodiment of a multifunction wireless charging pad according to the present invention. Moreover, FIG. 2 shows a first circuit block diagram of the first embodiment of the multifunction wireless charging pad. As shown in FIG. 1 and FIG. 2, the multifunction wireless charging pad 1 of the present invention mainly comprises: a body 11, a circuit module 12, and at least one lighting unit 14, wherein the body comprises a bottom case 1111 and a cover 112, and the cover 112 is provided with a pad area 113 and a wireless charging area 114 thereon. Moreover, the circuit module 12 is accommodated in the body 11 and coupled to a power source or a computer through an electrical connector 13. Please simultaneously refer to FIG. 3 and FIG. 4, wherein FIG. 3 depicts a diagram for describing the practical application of the first embodiment of the multifunction wireless charging pad, and FIG. 4 shows a second circuit block diagram of the first embodiment of the multifunction wireless charging pad. As the shown in FIG. 3 and FIG. 4, the circuit module 12 comprises a main controlling unit 121, a power supply unit 122, a current monitoring unit 123, and a first coil unit 124. Besides, according to FIG. 1 to FIG. 4, it is able to know that, the lighting unit 14 is connected to the body 10 and coupled to the main controlling unit 121. By such arrangements, when a wireless chargeable electronic device 2 integrated with a battery charging unit 22 and a battery 23 therein is positioned in the wireless charging area, the main controlling unit 121 enables the power supply unit 122 to convert the power source to an electricity having a specific power. According the standards of the Wireless Power Consortium, the specific power is in a range between 5 watts to 120 watts. It is worth noting that, the multifunction wireless charging pad further provide a standard mode and a fast charging mode.

Inheriting to above descriptions, after the conversion of the power source is accomplished, the power supply unit 122 further transmits the electricity to a coil element 21 of the wireless chargeable electronic device 2 through the first coil unit 124, such that the battery charging unit 22 is subsequently enabled to charge the battery 23 by using the electricity. Furthermore, according to design of the present invention, after the charging of the energy storing unit 23 is accomplished, the main controlling unit 121 stops transmitting the electricity to the first coil unit 124 by disabling the power supply unit 122. More particularly, the circuit module 12 further comprises one circuit board 120 accommodated in the body 11. Moreover, the main controlling unit 121 is disposed on the circuit board 120 for being electrically connected to the electrical connector 13, and the first coil unit 124 is coupled to the power supply unit 122. In the present invention, the electrical connector 13 is selected from the group consisting of USB connector, mini USB connector, micro USB connector, and Lightning connector. On the other hand, the wireless chargeable electronic device 2 is selected from the group consisting of mouse, tablet PC, smart watch, smart glasses, smart bracelet, and game controller. It is worth noting that, the current monitoring unit 123 would transmit an over-current signal to the main controlling unit 121 when finding that a current level of the current signal exceeds a threshold value.

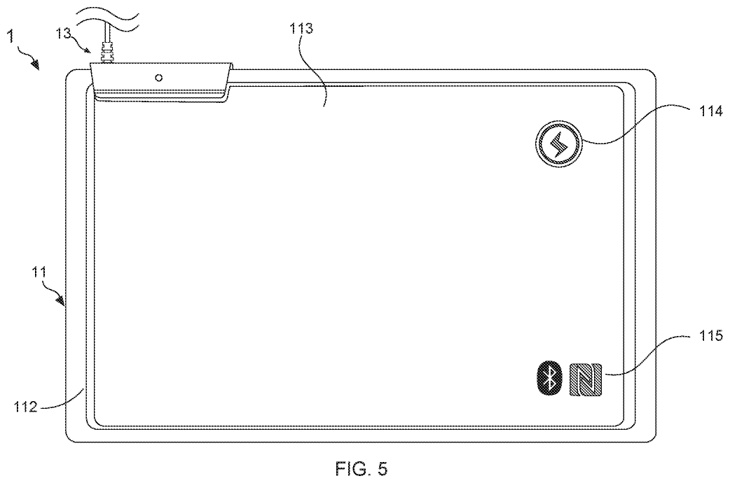

Referring to FIG. 1, FIG. 2, FIG. 3, and FIG. 4 again, and please simultaneously refer to FIG. 5, there is showing a top view of the first embodiment of the multifunction wireless charging pad. In the present invention, the multifunction wireless charging pad further comprises: a wireless communication unit 125, a data modulation/demodulation unit 126, a second coil unit 127, a full-bridge type controlling unit 128, an output port 129, an input port 12a, a data base 12b, and a lighting driver unit 12c. The wireless communication unit 125 and the data modulation/demodulation unit 126 are coupled to the current monitoring unit 123. As FIG. 5 shows, the body 11 is further provided with a wireless signal transmitting area 115, and the second coil unit 127 is coupled to the wireless communication unit 125. It is worth explaining that, the wireless chargeable electronic device 2 such as a smart phone 3 is able to communication with the computer through the wireless communication unit 125. Therefore, a main controlling element (e.g., microprocessor) of the smart phone 3 can achieve a function setting and/or a data transmitting of the smart phone 3 with the computer. It needs to further explain that, the wireless communication unit 125 is Bluetooth communication unit or near field communication unit.

As the shown provided in FIG. 2 and FIG. 5, the full-bridge type controlling unit 128 is coupled between the power supply unit 122 and the first coil unit 124, and simultaneously coupled to the main controlling unit 121. FIG. 2-FIG. 5 also depict that the output port 129 is coupled to the data modulation/demodulation unit 126. Besides, the input port 12a and the data base 12b are coupled to the current monitoring unit 123 and the main controlling unit 121, respectively. On the other hand, the lighting driver unit 12c is coupled between the main controlling unit 121 and the lighting unit 14, and also coupled to the data base 12b and the data modulation/demodulation unit 126. By such arrangements, when the wireless chargeable electronic device 2 is positioned in the wireless charging area 114 for electricity charging, the main controlling unit 121 enables the lighting driver unit 12c to drive the lighting unit 14 to emit a corresponding situation light according at least one light display data stored in the data base 12b. It is worth explaining that, the wireless chargeable electronic device 2 is able to communicate with the computer through the output port 129, so as to make a main controlling element disposed in the wireless chargeable electronic device 2 carry out a data transmission and a function setting with the computer.

Referring to FIG. 4 again, in which the multifunction wireless charging pad 1 of the present invention further comprises a buzzer driving unit 12d and a flexible speaker 12e. From FIG. 4, it is understood that the buzzer driving unit 12d is disposed in the body 11 and electrically connected to the main controlling unit 121. Moreover, the flexible speaker 12e is disposed in the body 11 and electrically connected to the buzzer driving unit 12d. Therefore, when the wireless chargeable electronic device 2 is positioned in the wireless charging area 114 for electricity charging, the main controlling unit 121 enables the buzzer driving unit 12d to driver the flexible speaker 12e to broadcast a corresponding situation sound according at least one sound broadcast data stored in the data base 12b. More particularly, the situation sound is selected form the group consisting of enable wireless charging sound, disable wireless charging sound, warning sound, and music.

### Second Embodiment

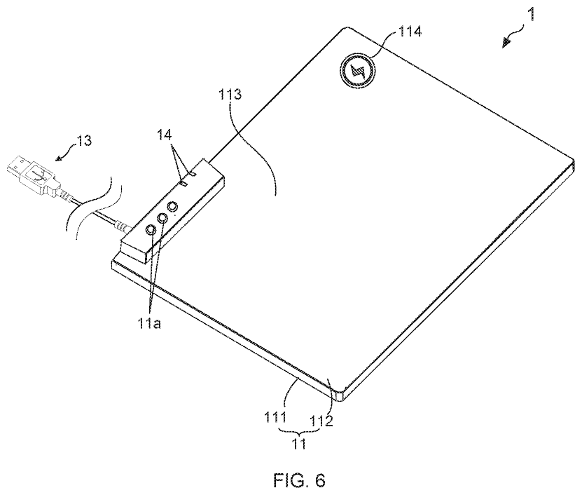

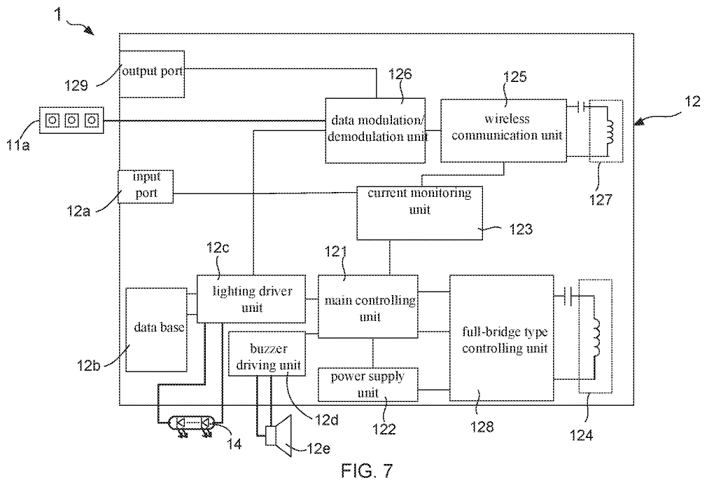

Continuously referring to FIG. 4 and FIG. 5, and please simultaneously refer to FIG. 6 and FIG. 7, which respectively show a stereo diagram of a second embodiment of the multifunction wireless charging pad a circuit block diagram of the second embodiment. After comparing FIG. 4 with FIG. 7, it is able to know that, the second embodiment further comprises a situation choosing unit 11a. As the shown provided in FIG. 7, the situation choosing unit 11a is disposed in the body 11, and is electrically connected to the main controlling unit 121 and the data modulation/demodulation unit 126. Besides, the main controlling unit 121 enables the lighting driver unit 12c to driver the lighting unit 14 to emit the corresponding situation light according the light display data designated through the situation choosing unit 11a. Also, the main controlling unit 121 enables the buzzer driving unit 12d to driver the flexible speaker 14 to broadcast the corresponding situation sound according the sound broadcast data designated through user pressed the situation choosing unit 11a.

Inheriting to above descriptions, after user operates the situation choosing unit 11a, the situation choosing unit 11a transmits a chosen signal to the data modulation/demodulation unit 126, such that the data modulation/demodulation unit modulates the chosen signal to a status code. As a result, the lighting driver unit 12c drives the lighting unit 14 to emit the corresponding situation light based on the status code. It is needs to specifically explain that, the situation light is selected from the group consisting of enable wireless charging light, disable wireless charging light, warning light, breath light, game light, emotion light, and wireless charging status light. Moreover, the lighting unit is selected from the group consisting of light-emitting diode and organic light emitting diode. It is noted that, facilitate the operation of the mouse, the supporting portion is disposed on the surface of the bottom case 111 used for adjusting the tile angles and height of the body 11.

### Third Embodiment

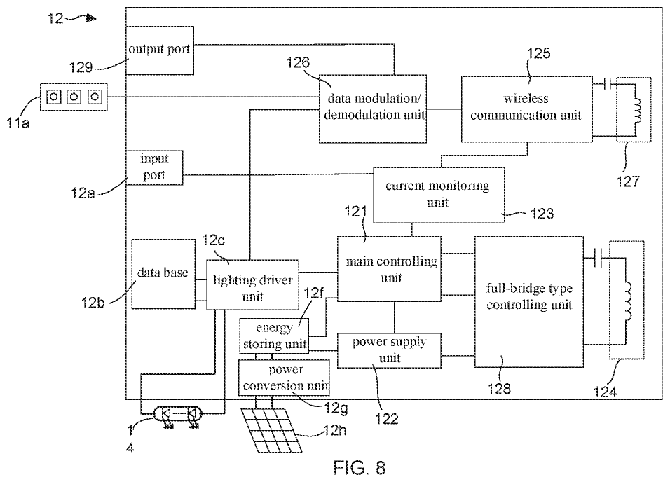

Continuously referring to FIG. 7, and please simultaneously refer to FIG. 8, there is showing a circuit block diagram of a third embodiment of the multifunction wireless charging pad. After comparing FIG. 7 with FIG. 8, it is able to know that, the circuit module 12 of third embodiment further comprises an energy storing unit 12f, a power conversion unit 12g, and a solar panel 12h. The energy storing unit 12f is disposed in the body 11, and is electrically connected between the main controlling unit 121 and the power supply unit 122. Moreover, the power conversion unit 12g is disposed in the body 11, and is electrically connected to the main controlling unit 121 and the energy storing unit 12f. FIG. 8 also depicts that the solar panel 12h is disposed on the body 11 and electrically connected to power conversion unit 12g. It is worth explaining that, when the charging of the energy storing unit 12f is accomplished, the main controlling unit 121 disable the power conversion unit 12g to stop transmitting electricity to the energy storing unit 12f.

Through above descriptions, the multifunction wireless charging pad 1 of the present invention has been introduced completely and clearly; in summary, the present invention includes the advantages of:

(1) In view of the fact that conventional multifunction wireless mice have considerable power consumption during the operation thereof, the present invention particularly provides a multifunction wireless charging pad 1, not only having functions of mouse pad and wireless charging, but also capable of transmitting data to any kinds of wireless chargeable electronic devices 2 by Bluetooth communication or near field communication. The multifunction wireless charging pad 1 of the present invention mainly comprises a body 11, a circuit module 12 and at least one lighting unit 14. When the wireless chargeable electronic device 2 such as a mouse or a smart phone 3 is positioned on the multifunction wireless charging pad 1 for electricity charging, a main controlling unit 121 in the circuit module 12 controls the lighting unit 14 to emit a corresponding situation light, so that user is able to know the charging state of the wireless chargeable electronic device 2 or other operation state according the variation of the situation light. In addition, the smart phone 3 is able to communicate with a computer through the function of the near field communication or Bluetooth communication, such that the smart phone 3 is able to carry out a data transmission and a function setting with the computer. It is needs to specifically explain that, the wireless chargeable electronic device 2 is able to communicate with the computer through the output port such as a USB port of the multifunction wireless charging pad 1, and provided a function setting, a data transmitting, and electricity charging.

The above description is made on embodiments of the present invention. However, the embodiments are not intended to limit scope of the present invention, and all equivalent implementations or alterations within the spirit of the present invention still fall within the scope of the present invention.

What is claimed is:

1. A multifunction wireless charging pad, comprising:
a body, being provided with a pad area and a wireless charging area thereon;
a circuit module, being accommodated in the body and coupled to a power source or a computer through an electrical connector; wherein the circuit module comprises a main controlling unit, a power supply unit, a current monitoring unit, and a first coil unit; and
at least one lighting unit, being connected to the body and coupled to a lighting driver unit;
wherein when a wireless chargeable electronic device having a battery charging unit and a battery is positioned in the wireless charging area, the main controlling unit enables the power supply unit to convert the power source to an electricity having a specific power;
wherein the electricity is further transmitted to a coil element of the wireless chargeable electronic device through the first coil unit, the battery charging unit is enabled to charge the battery by using the electricity.

2. The multifunction wireless charging pad of claim 1, wherein the circuit module further comprises:
at least one circuit board, being accommodated in the body, wherein the main controlling unit is disposed on the circuit board and electrically connected to the electrical connector;
wherein the power supply unit is disposed on the circuit board and coupled to the main controlling unit and the first coil unit;
wherein the current monitoring unit is coupled between the main controlling unit and the electrical connector, for sampling at least one current signal transmitted between the main controlling unit and the electrical connector;
wherein the current monitoring unit transmits an over-current signal to the main controlling unit when finding that a current level of the current signal exceeds a threshold value.

3. The multifunction wireless charging pad of claim 1, wherein the body comprises a bottom case and a cover, and the specific power is in a range between 5 watts to 120 watts.

4. The multifunction wireless charging pad of claim 1, wherein the electrical connector is selected from the group consisting of USB connector, mini USB connector, micro USB connector, and Lightning connector.

5. The multifunction wireless charging pad of claim 1, wherein the wireless chargeable electronic device is selected from the group consisting of mouse, tablet PC, smart watch, smart glasses, smart bracelet, and game controller.

6. The multifunction wireless charging pad of claim 2, further comprising:
a wireless communication unit, being coupled to the current monitoring unit; and
a data modulation/demodulation unit, being coupled to the current monitoring unit;
wherein the body is further provided with a wireless signal transmitting area;
wherein the wireless chargeable electronic device is able to communicate with the computer through the wireless communication unit, such that a function setting and a data transmitting of the wireless chargeable electronic device by a main controlling element disposed in the wireless chargeable electronic device.

7. The multifunction wireless charging pad of claim 6, further comprising:
a second coil unit, being coupled to the wireless communication unit.

8. The multifunction wireless charging pad of claim 6, further comprising:
a full-bridge type controlling unit, being coupled to the power supply unit and the first coil unit;
an output port, being coupled to the data modulation/demodulation unit; and
an input port, being coupled to the current monitoring unit and used for connecting to the computer;
wherein the wireless chargeable electronic device is connected to the computer through the output port, so as to make a main controlling element disposed in the wireless chargeable electronic device carry out a data transmission and a function setting of the wireless chargeable electronic device.

9. The multifunction wireless charging pad of claim 6, further comprising:
a data base, being coupled to main controlling unit; and
wherein the lighting driver unit is coupled between the main controlling unit and the lighting unit;
wherein when the wireless chargeable electronic device is positioned in the wireless charging area for electricity charging, the main controlling unit enables the lighting driver unit to driver the lighting unit to emit a corresponding situation light according at least one light display data stored in the data base.

10. The multifunction wireless charging pad of claim 9, further comprising:
a buzzer driving unit, being disposed in the body and electrically connected to the main controlling unit; and
a flexible speaker, being disposed in the body and electrically connected to the buzzer driving unit;
wherein when the wireless chargeable electronic device is positioned in the wireless charging area for electricity charging, the main controlling unit enables the buzzer driving unit to driver the flexible speaker to broadcast a corresponding situation sound according a sound broadcast data stored in the data base.

11. The multifunction wireless charging pad of claim 10, further comprising:
a situation choosing unit, being disposed in the body and electrically connected to the main controlling unit and the data modulation/demodulation unit;
wherein the main controlling unit enables the buzzer driving unit to driver the flexible speaker to broadcast the corresponding situation sound according the sound broadcast data designated through the situation choosing unit;
wherein the main controlling unit enables the lighting driver unit to driver the lighting unit to emit the corresponding situation light according the light display data designated through the situation choosing unit.

12. The multifunction wireless charging pad of claim 11, wherein situation light is selected from the group consisting of enable wireless charging light, disable wireless charging light, warning light, breath light, rainbow light, game light, emotion light, and wireless charging status light.

13. The multifunction wireless charging pad of claim 11, wherein the situation choosing unit through the way of transmitting a chosen signal to the data modulation/demodulation unit, so as to the data modulation/demodulation unit modulate the chosen signal to a status code, therefore the lighting driver unit driver the lighting unit to emit the corresponding situation light based on the status code.

14. The multifunction wireless charging pad of claim 3, wherein the body further comprises:
a supporting portion, being disposed on the surface of bottom case used for adjusting the tilt angles and height of the body.

15. The multifunction wireless charging pad of claim 1, wherein the lighting unit is selected from the group consisting of light-emitting diode and organic light-emitting diode.

16. The multifunction wireless charging pad of claim 2, wherein the circuit module further comprises:
an energy storing unit, being disposed in the body and electrically connected between the main controlling unit and the power supply unit;
a power conversion unit, being disposed in the body and electrically connected to the main controlling unit and the energy storing unit; and
a solar panel, being disposed on the body and electrically connected to the energy storing unit;
wherein when the charging of the energy storing unit is accomplished, the main controlling unit disable the power conversion unit to stop transmitting electricity to the energy storing unit.

17. The multifunction wireless charging pad of claim 10, wherein situation sound is selected from the group consisting of enable wireless charging sound, disable wireless charging sound, warning sound, and music.

18. The multifunction wireless charging pad of claim 6, wherein the wireless communication unit is Bluetooth communication unit.

19. The multifunction wireless charging pad of claim 6, wherein the wireless communication unit is near field communication unit.
